(19) United States
(12) Patent Application Publication
(10) Pub. No.: US 2007/0241411 A1
(43) Pub. Date: Oct. 18, 2007

(54) STRUCTURES AND METHODS FOR FORMING SRAM CELLS WITH SELF-ALIGNED CONTACTS

(75) Inventors: Haining S. Yang, Wappingers Falls, NY (US); Robert C. Wong, Poughkeepsie, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: International Business Machines Corporation, Armonk, NY (US)

(21) Appl. No.: 11/279,413

(22) Filed: Apr. 12, 2006

(51) Int. Cl. H01L 29/94

(52) U.S. Cl. 257/383; 257/E27.009

(57) ABSTRACT

The present invention relates to a semiconductor device comprising at least one static random access memory (SRAM) cell with self-aligned contacts. Specifically, the at least one SRAM cell comprises at least a first gate conductor that is located over a channel region between a source region and a drain region. The first gate conductor is covered by a dielectric cap comprising a protective dielectric material, and the source and drain regions are covered by non-protective dielectric material(s) that can be selectively removed against the protective material. In this manner, a self-aligned source or drain contact can be formed through the non-protective dielectric material(s) to contact either the source or the drain region, while the dielectric cap protects the first gate conductor during formation of the source or drain contact opening and thereby prevents shorting between the first gate conductor and the source or drain contact to be formed.

### FIELD OF THE INVENTION

This invention relates to semiconductor devices that comprise static random access memory (SRAM) cells. More specifically, the present invention relates to SRAM cells with self-aligned contacts, as well as to methods for fabricating such SRAM cells.

### BACKGROUND OF THE INVENTION

A static random access memory (SRAM) is a significant memory device due to its high speed, low power consumption, and simple operation. Unlike a dynamic random access memory (DRAM) cell, the SRAM does not need to regularly refresh the stored data and it has a straightforward design.

Each bit in a typical six-transistor SRAM (6T-SRAM) cell is stored on four transistors, generally referred to as load transistors (or pull-up transistors) and driver transistors (or pull-down transistors), that form a flip-flop circuit containing two cross-coupled inverters. This storage cell has two stable states which are used to denote 0 and 1. Two additional access transistors (or pass-gate transistors) serve to control the access to a storage cell during read and write operations.

FIG. 1 shows a top-down view of an exemplary 6T-SRAM-cell layout, which contains active regions (i.e., doped-well regions), gate structures, and contact structures that may be used to form typical metal-oxide-semiconductor (MOS) transistors in a typical complementary metal-oxide-semiconductor (CMOS) SRAM cell. Specifically, pass-gate transistors 1 and 4 and pull-down transistors 2 and 3 are formed within active regions 12 and 14, and pull-up transistors 5 and 6 are formed within active regions 16 and 18. The active regions 12, 14, 16, and 18 are formed within a semiconductor substrate 10, which may preferably be a silicon substrate doped with n-type and p-type impurities in the vicinity of the p-channel transistors and the n-channel transistors, respectively. Gate structures 22 and 26 are arranged above active region 12 to form gates for the pull-down transistor 2 and the pass-gate transistor 1, respectively. Similarly, above active region 14, gate structures 24 and 28 are arranged to form gates for the pull-down transistor 3 and the pass-gate transistor 4, respectively. Consequently, active regions 16 and 18 each have two gate structures 22 and 24 arranged above them.

Each SRAM cell typically contains 6-10 contacts for accessing the transistors contained therein. Specifically, the SRAM contacts can be divided into two categories: (1) gate contacts G that are formed directly over the gate structures 26 and 28, and (2) source or drain contacts SD that are formed directly over source or drain regions of the transistors 1-6 in the SRAM cell. On one hand, the gate contacts G are located outside of any active region of the SRAM cell, so the risk of shorting between the gate contacts G and any source or drain region of the SRAM cell is low. On the other hand, the source or drain contacts SD are located immediately adjacent to one or more gate structures 22, 24, 26 and 28. Therefore, the risk of shorting between the source or drain contacts SD and the gate structures 22, 24, 26, and 28 is high.

FIG. 2A shows a cross-sectional view of a gate contact G of the conventional SRAM cell along Line I-I of FIG. 1, and FIG. 2B shows a cross-sectional view of two source/drain contacts SD of the conventional SRAM cell along Line II-II of FIG. 1. Specifically, the source/drain contacts SD are located directly over the source and drain regions 112 and 114 of the transistor 2, which are located in the active region 12 of the SRAM cell. The gate structure 22, which is located over a channel region between the source and drain regions 112 and 114, comprises a gate dielectric layer 116A, a gate conductor 118A having an optional gate silicide layer 119A, and optional sidewall spacers 120A and 122A. The gate contact G is located directly over the gate structure 26, which is located over the semiconductor substrate 10 outside of any active region of the SRAM cell and which also comprises a gate dielectric layer 116B, a gate conductor 118B having an optional gate silicide layer 119B, and optional sidewall spacers 120B and 122B.

A blanket silicon nitride layer 124 and an interlevel dielectric (ILD) layer 102 are provided over the entire SRAM cell, including the gate structures 22 and 26 and the source and drain regions 112 and 114 of the transistor 2. Subsequently, contact openings (not shown) are formed through the blanket silicon nitride layer 124 and the ILD layer onto the source and drain regions 112 and 114 of the transistor 2 and the gate conductor 118B of the gate structure 26 by lithography and non-selective etching. Note that no contact opening is formed onto the gate conductor 118A of the gate structure 22. The contact openings so formed are then filled with a conductive material to form the gate contact G and the source/drain contacts SD, as shown in FIGS. 2A and 2B.

However, lithography is an error-prone process. Slight misalignment between the source/drain contact openings (which are defined by the lithographic pattern) and the source/drain regions 112 and 114 may result in deleterious shorting between the source/drain contacts SD and the adjacent gate conductor 118A of the gate structure 22.

As the 45 nm node and the 32 nm node generations of CMOS devices are approached, scaling of the SRAM cell becomes imperative, because more than two thirds of the area on a typical microprocessor chip is occupied by SRAM arrays. Unfortunately, error margin of the lithographic process is un-scalable, so scaling of the SRAM cells significantly increases the risk of shorting between the source/drain contacts and the adjacent gate structures in the SRAM cells.

There is a need for self-aligned SRAM contacts that can be formed at reduced dimensions without increasing the risk of shorting between the source/drain contacts and the adjacent gate structures in the SRAM cells.

### SUMMARY OF THE INVENTION

The present invention solves the above-described problems by providing improved SRAM structures with self-aligned contacts that can be formed using a selective-etching process. Such a selective-etching process is highly resistant to lithographic error, and it allows further scaling of the SRAM cells without increasing the risk of shorting between the source/drain contacts and the adjacent gate structures in the SRAM cells.

In one aspect, the present invention relates to a semiconductor device comprising at least one static random access memory (SRAM) cell having at least a first gate conductor located over a channel region between a source region and a drain region, wherein the first gate conductor is covered by a dielectric cap comprising a protective dielectric material, wherein the source and drain regions are covered by non-protective dielectric material(s) that can be selectively removed against the protective material, wherein the first gate conductor has no gate contact located thereover, and wherein at least one of the source and drain regions has a source or drain contact located thereover.

In a specific embodiment of the present invention, the protective dielectric material comprises silicon nitride. More preferably, the semiconductor device further comprises one or more silicon nitride spacers along sidewalls of the first gate conductor.

In an alternative embodiment of the present invention, the protective dielectric material comprises silicon carbide. More preferably, the semiconductor device further comprises one or more silicon carbide spacers along sidewalls of the first gate conductor.

Other dielectric materials, such as silicon oxynitride, silicon carbonitride, silicon carboxide, etc., can also be used as the protective dielectric material, provided that such other dielectric materials is resistant to the etching chemistry that selectively removes the non-protective dielectric material(s), such as silicon oxide or silicon nitride.

In summary, any suitable combination of protective and non-protective dielectric materials can be chosen for the practice of the present invention, provided that the chosen material combination enables selective removal of the protective dielectric material against the non-protective dielectric material(s) by a specific etching chemistry.

Preferably, but not necessarily, the first gate conductor comprises a gate silicide layer.

In another aspect, the present invention relates to a semiconductor device comprising at least one SRAM cell having at least a first gate conductor located over a channel region between a source region and a drain region and a second gate conductor located outside of any active region of the SRAM cell, wherein the first gate conductor is covered by a dielectric cap comprising a protective dielectric material, wherein the second gate conductor and the source and drain regions are covered by non-protective dielectric material(s) that can be selectively removed against the protective material, wherein the first gate conductor has no gate contact located thereover, wherein the second gate conductor has a gate contact located thereover, and wherein at least one of the source and drain regions has a source or drain contact located thereover.

When the protective dielectric material comprises silicon nitride, the semiconductor device preferably further comprises one or more silicon nitride spacers along sidewalls of both the first and second gate conductors. Alternatively, when the protective dielectric material comprises silicon carbide, the semiconductor device preferably further comprises one or more silicon carbide spacers along sidewalls of both the first and second gate conductors.

Preferably, but not necessarily, each of the first and second gate conductors comprises a gate silicide layer.

In another aspect, the present invention relates to a method for forming a semiconductor device, comprising:
forming at least one static random access memory (SRAM) cell having at least first and second gate conductors, wherein the first gate conductor is located over a channel region between a source region and a drain region, and wherein the second gate conductor is located outside of any active region of the SRAM cell;
selectively forming a dielectric cap over the first gate conductor, wherein the dielectric cap comprises a protective dielectric material;
depositing one or more non-protective dielectric layers over the at least one SRAM cell, wherein the one or more non-protective dielectric layers comprise non-protective dielectric material(s) that can be selectively removed against the protective dielectric material;
selectively removing portions of the one or more non-protective dielectric layers to form at least a gate contact opening that extends through the one or more non-protective dielectric layers onto an upper surface of the second gate conductor and a source or drain contact opening that extends through the one or more non-protective dielectric layers onto an upper surface of either the source or the drain region, wherein the dielectric cap protects the first gate conductor during selective removal of the non-protective dielectric material(s) and prevents extension of the source or drain contact opening onto the first gate conductor; and
filling the gate contact opening and the source or drain contact opening with a conductive material, thereby forming at least a gate contact that is located directly over the second gate conductor and a source or drain contact that is located directly over the source or drain region, wherein no gate contact is located over the first gate conductor.

When the protective dielectric material comprises silicon nitride, a reactive ion etching (RIE) step employing a CHF₃-containing or a C₄F₈/CO-containing chemistry is preferably used for the selective removal of the non-protective dielectric material(s). Other etching chemistries can also be used for conducting the RIE step, as long as such other etching chemistries allow selective removal of the non-protective dielectric material(s) against silicon nitride.

Alternatively, when the protective dielectric material comprises silicon carbide, a reactive ion etching (RIE) step employing a fluorine-containing chemical, such as CF₄, is preferably used for the selective removal of the non-protective dielectric material(s). Other chemicals can also be used for conducting the RIE step, as long as such other chemicals allow selective removal of the non-protective dielectric material(s) against silicon carbide.

Preferably, but not necessarily, the dielectric cap is formed by:
selectively removing an upper portion of the first gate conductor to form a recess thereover;
depositing a blanket layer of the protective dielectric material over both the first and second gate conductor; and
removing a portion of the protective dielectric material from the first and second gate conductor, wherein another portion of the protective dielectric material remains in the recess located over the first gate conductor and thereby forms the dielectric cap.

Other aspects, features and advantages of the invention will be more fully apparent from the ensuing disclosure and appended claims.

### BRIEF DESCRIPTION OF THE DRAWINGS

FIG. 1 shows a top view of a conventional SRAM cell with gate contacts located directly over gate structures and source/drain contacts located directly over source and drain regions of SRAM transistors.

FIG. 2A shows a cross-sectional view of the conventional SRAM cell of FIG. 1 along Line I-I.

FIG. 2B shows a cross-sectional view of the conventional SRAM cell of FIG. 1 along Line II-II.

FIGS. 3A and 3B show cross-sectional views of an improved SRAM cell (along Lines I-I and II-II, respectively) comprising a first gate conductor with a silicon nitride cap formed thereover and a second gate conductor with a gate contact formed thereover, according to one embodiment of the present invention.

FIGS. 4A-14B are cross-sectional views that illustrate exemplary processing steps for forming the improved SRAM cell of FIGS. 3A and 3B.

FIGS. 15A and 15B shows cross-sectional views of an improved SRAM cell (along Lines I-I and II-II, respectively) comprising a first gate conductor with a silicon carbide cap formed thereover and a second gate conductor with a gate contact formed thereover, according to one embodiment of the present invention.

FIGS. 16A-24B are cross-sectional views that illustrate exemplary processing steps for forming the improved SRAM cell of FIGS. 15A and 15B.

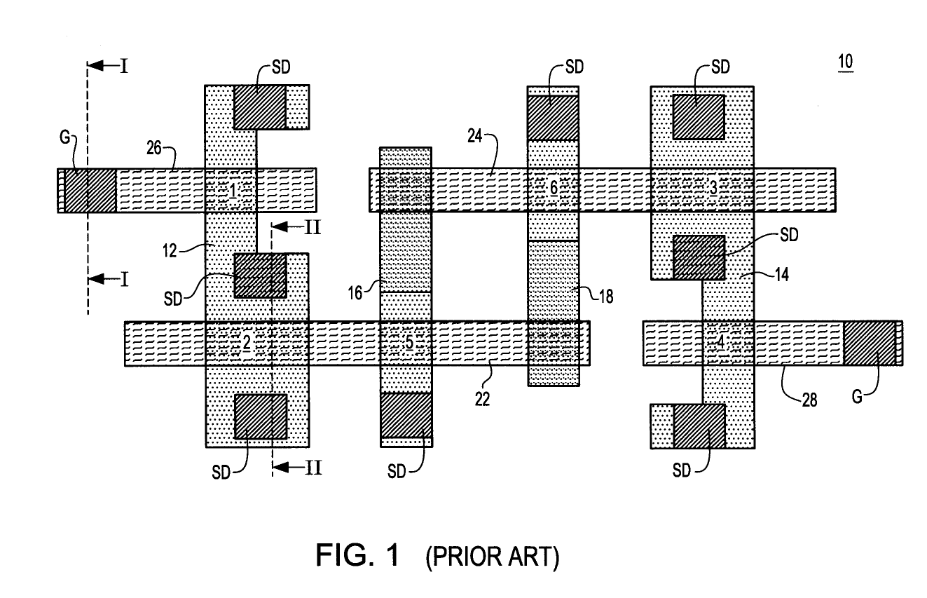

### DETAILED DESCRIPTION OF THE INVENTION, AND PREFERRED EMBODIMENTS THEREOF

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The present invention provides a SRAM cell structure that comprises at least a first gate conductor located over a channel region between a source region and a drain region. The first gate conductor is covered by a dielectric cap formed of a protective dielectric material, while the source and drain regions are covered by non-protective dielectric material(s) that can be selectively removed against the protective dielectric material.

In this manner, a source or drain contact opening can be formed over either the source or the drain region by selectively removing the non-protective dielectric material(s), when the dielectric cap protects the first gate conductor and prevents the source or drain contact opening from extending onto the first gate conductor. Therefore, the resulting source or drain contact will not short to the first gate conductor, even if the lithographic pattern used for forming the source or drain contact opening is misaligned.

More preferably, the SRAM cell structure further comprises a second gate conductor that is located outside of any active region of the SRAM cell. The second gate conductor is also covered by non-protective dielectric material(s), so that a gate contact opening can be formed over the second gate conductor by selectively removing the non-protective dielectric material(s). In this manner, the present invention enables selective formation of gate contacts over certain gate conductors, while preventing formation of gate contacts over other gate conductors. The selectivity of the gate contact formation is ensured by presence of the dielectric caps over such other gate conductors.

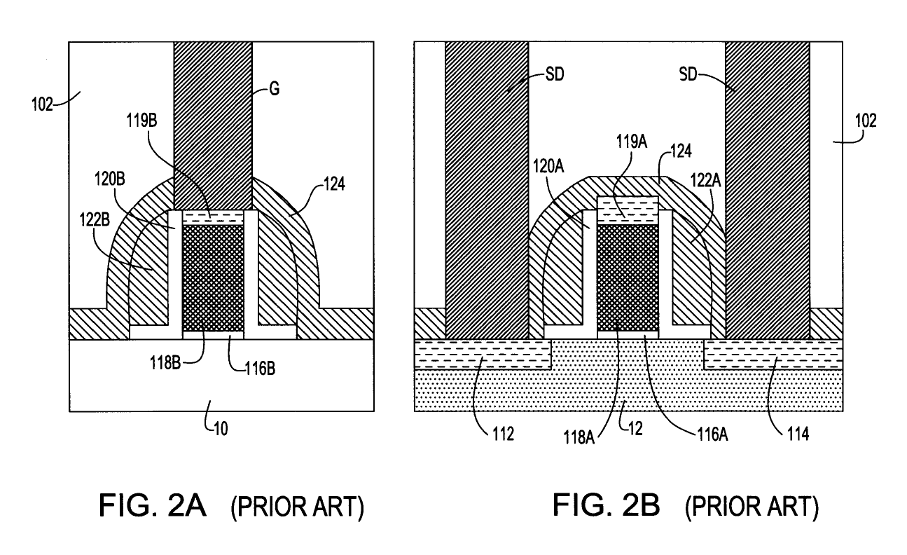

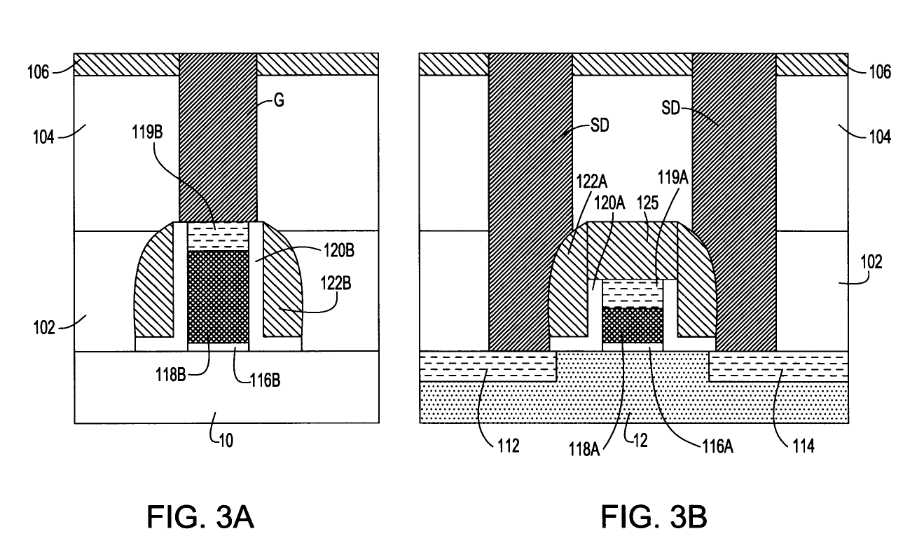

FIGS. 3A and 3B show cross-sectional views of an improved SRAM cell similar to the conventional SRAM cell of FIGS. 2A and 2B, except that the improved SRAM cell does not contain the blanket silicon nitride layer 124 and that the gate conductor 118A of the gate structure 22 is selectively covered by a dielectric cap 125.

Specifically, the dielectric cap 125 comprises a protective dielectric material that is not present over the source and drain regions 112 and 114 or the gate conductor 118B of the gate structure 26. The source and drain regions 112 and 114 and the gate conductor 118B of the gate structure 26 are instead covered by two interlevel dielectric (ILD) layers 102 and 104 that comprise non-protective dielectric material(s) that can be selectively removed against the protective dielectric material in the dielectric cap 125. An optional interlevel-capping layer 106 may further be provided over the upper ILD layer 104.

In this manner, contact openings can be readily formed over the gate conductor 118B of the gate structure 26 and the source and drain regions 112 and 114 by selectively removing a portion of the non-protective dielectric material(s) in the ILD layers 102 and 104, while the gate conductor 118A of the gate structure 22 is protected by the dielectric cap 125. Consequently, the source/drain contacts SD will not short with the gate conductor 118A of the gate structure 22, despite the presence of any lithographic alignment error. In other words, the source/drain contacts SD are “self-aligned” against the gate conductor 118A of the gate structure 22.

Preferably, but not necessarily, the dielectric cap 125 comprises silicon nitride, and the ILD layers 102 and 104 comprises any suitable interlevel dielectric material other than silicon nitride, so that a selective etching process that selectively etches the ILD layers 102 and 104 against silicon nitride can be readily used for forming contact openings over the gate conductor 118B and the source/drain regions 112 and 114, but not over the gate conductor 118A. More preferably, a reactive ion etching (RIE) process employing a CHF₃-containing or a C₄F₈/CO-containing etching chemistry is used for forming the contact opening.

In a particularly preferred, but not necessary, embodiment of the present invention as shown in FIGS. 3A and 3B, the gate structures 22 and 26 comprise sidewall spacers 120A, 120B, 122A and 122B along sidewalls of the gate conductors 118A and 118B. The inner sidewall spacers 120A and 120B may comprise either protective or non-protective dielectric material(s), while the outer sidewall spacers 122A and 122B comprise the protective dielectric material. Therefore, the outer sidewall spacers 122A and 122B function to protect the sidewalls of the gate conductors 118A and 118B during formation of the contact openings.

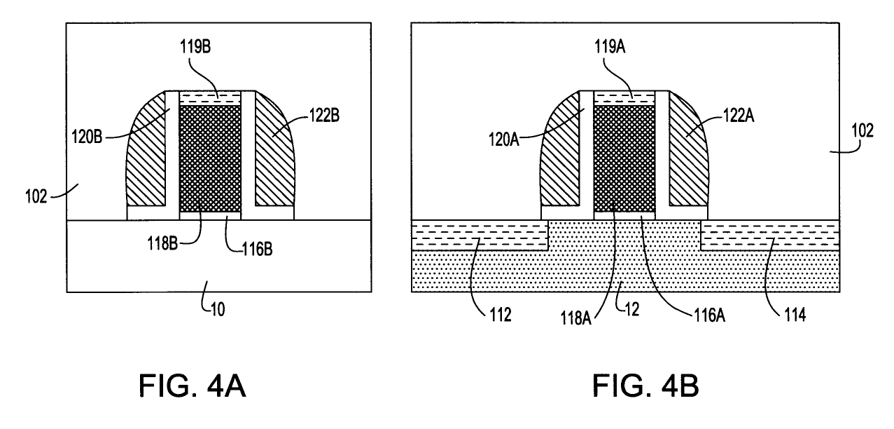

An exemplary method for forming the improved SRAM cell of FIGS. 3A and 3B is illustrated by FIGS. 4A-14B.

First, a SRAM cell having the same configuration for both gate structures 22 and 26 are formed. Specifically, the gate structures 22 and 26 each comprises a gate dielectric layer (116A or 116B), a gate conductor (118A or 118B) with an optional gate silicide layer thereover (119A or 119B), a silicon oxide sidewall spacer (120A or 120B), and a silicon nitride sidewall spacer (122A or 122B), as shown in FIGS. 4A and 4B. A first ILD layer 102, which may comprise any suitable interlevel dielectric material other than silicon nitride, is provided over the entire SRAM cell.

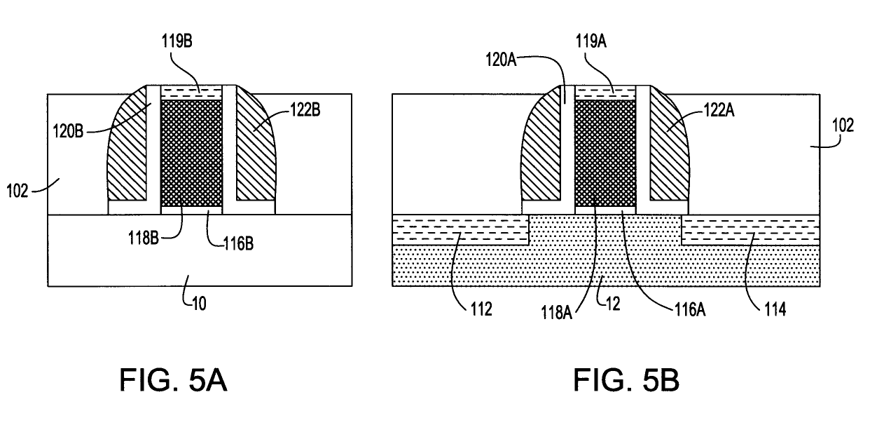

The first interlevel dielectric layer 102 is then recessed by either a chemical mechanical polishing (CMP) step or a selective etching step to expose upper surfaces of the gate silicide layer 119A and 119B of the gate conductor 118A and 118B, as shown in FIGS. 5A and 5B.

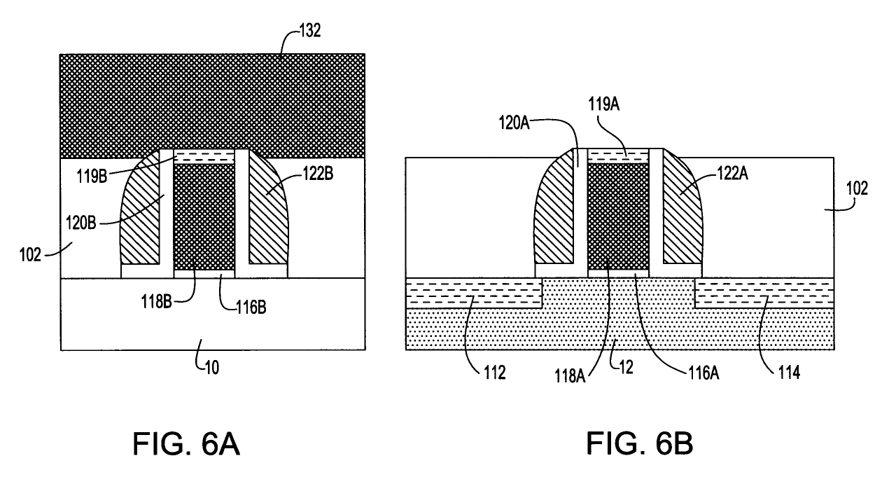

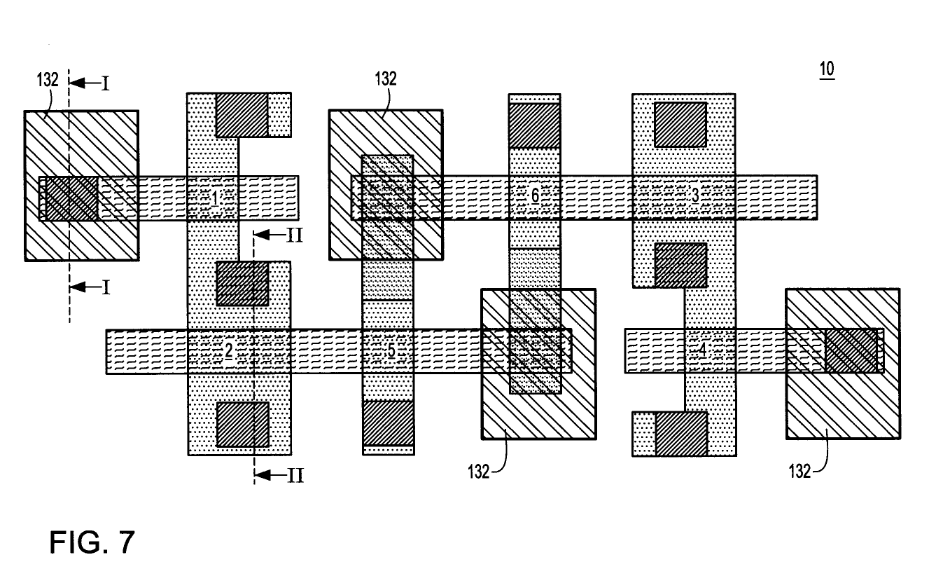

Next, a patterned resist layer 132 is formed over the SRAM cell to selectively cover portions of the SRAM cell, but other portions of the SRAM cell are left exposed. Specifically, the gate conductor 118B and its gate dielectric layer 119B of the gate structure 26 are selectively covered by the patterned resist layer 132, while the gate conductor 118A and its gate dielectric layer 119A of the gate structure 22 are exposed, as shown in FIGS. 6A and 6B. FIG. 7 shows a top view of the SRAM cell, where the patterned resist layer 132 selectively covers certain areas of the SRAM cell while exposing others.

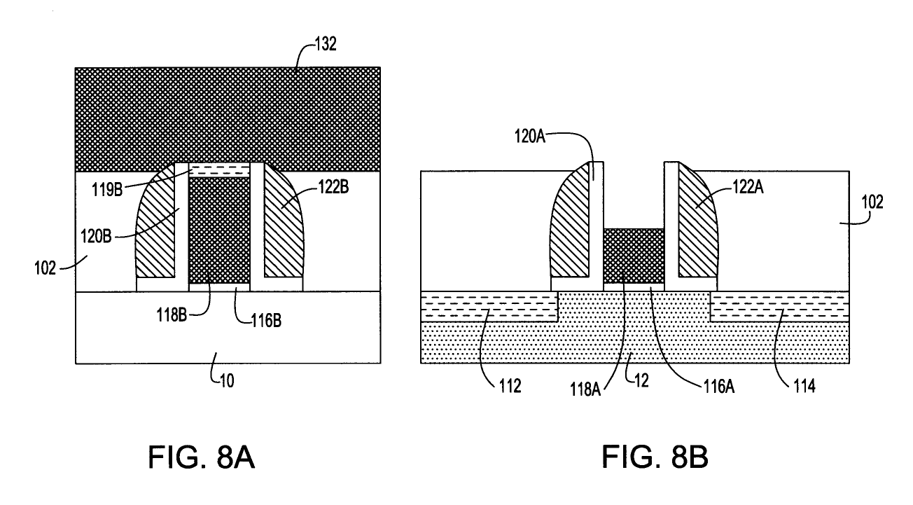

Subsequently, a selective etching process is carried out to selectively remove an upper portion of the gate conductor 118A (including the gate silicide layer 119A), thereby forming a recess over the gate conductor 118A in the gate structure 22, as shown in FIGS. 8A and 8B. Meanwhile, the patterned resist layer 132 protects the gate conductor 118B and its gate silicide layer 119B of the gate structure 26.

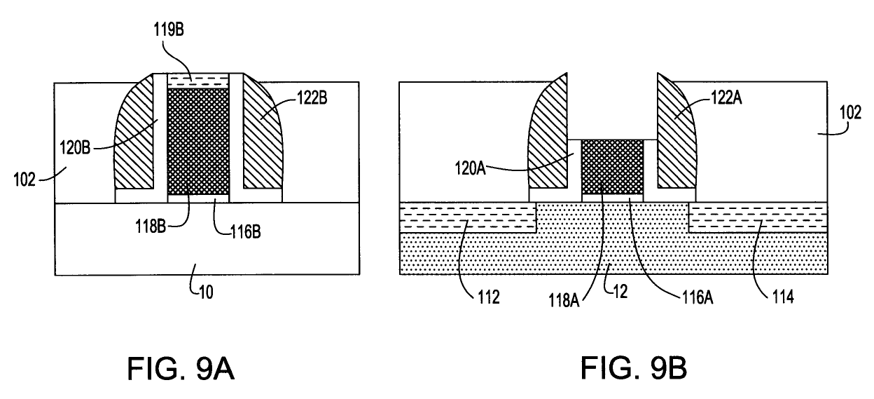

After removal of the upper portion of the gate conductor 118A, the patterned resist layer 132 is removed from the SRAM cell by stripping, as shown in FIGS. 9A and 9B. The resist stripping step may also remove an upper portion of the silicon oxide sidewall spacer 120A.

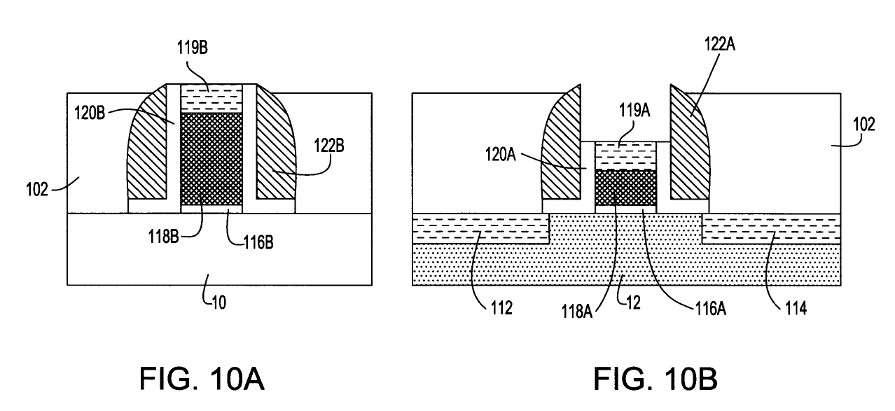

Because the gate silicide layer 119A of the gate conductor 118A is removed during the selective etching process, a silicidation process is preferably (but not necessarily) carried out to form a new gate silicide layer 119A in the recessed gate conductor 118A, as shown in FIGS. 10A and 10B.

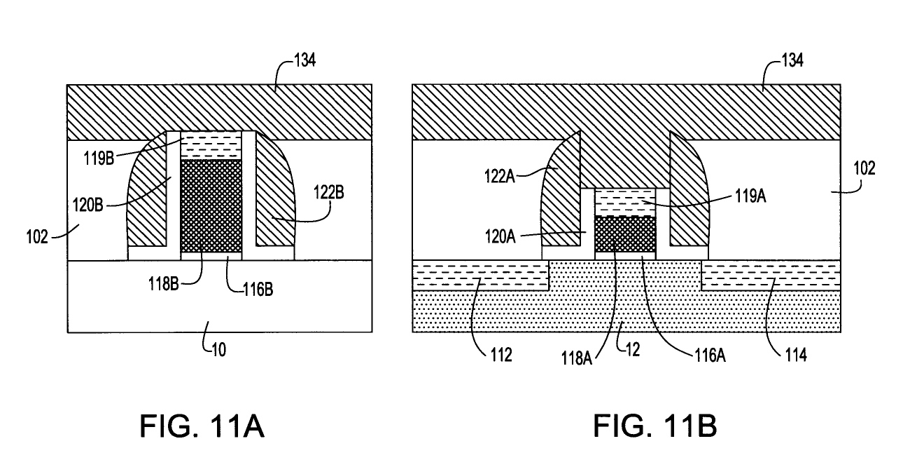

Next, a blanket layer 134 of a protective dielectric material is deposited over the entire SRAM cell, including the gate structures 22 and 26, as shown in FIGS. 11A and 11B. Preferably, the blanket layer 134 comprises silicon nitride. The blanket silicon nitride layer 134 can be readily formed by, for example, a low pressure chemical vapor deposition (LPCVD) process or a plasma enhanced chemical vapor deposition (PECVD) process, or by any other suitable deposition techniques well known in the art.

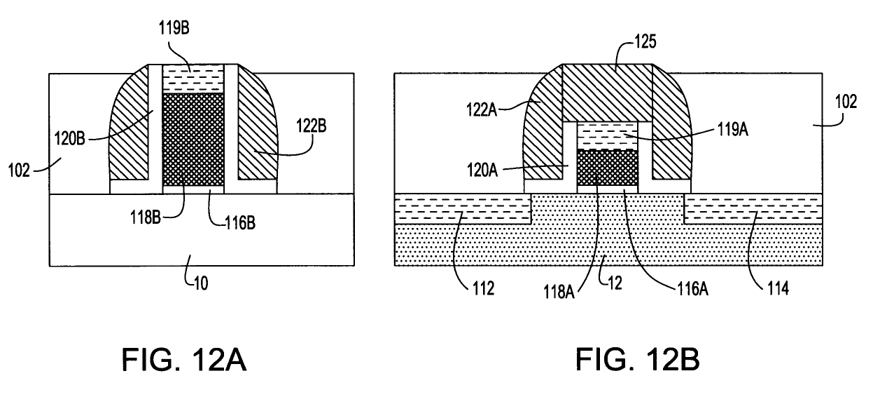

A planarization step, preferably a CMP step, is carried out to remove a portion of the blanket silicon nitride layer 134 from the gate structures 22 and 26, while another portion of the blanket silicon nitride layer 134 remains in the recess located over the gate conductor 118A and thereby forms the silicon nitride cap 125, as shown in FIGS. 12A and 12B.

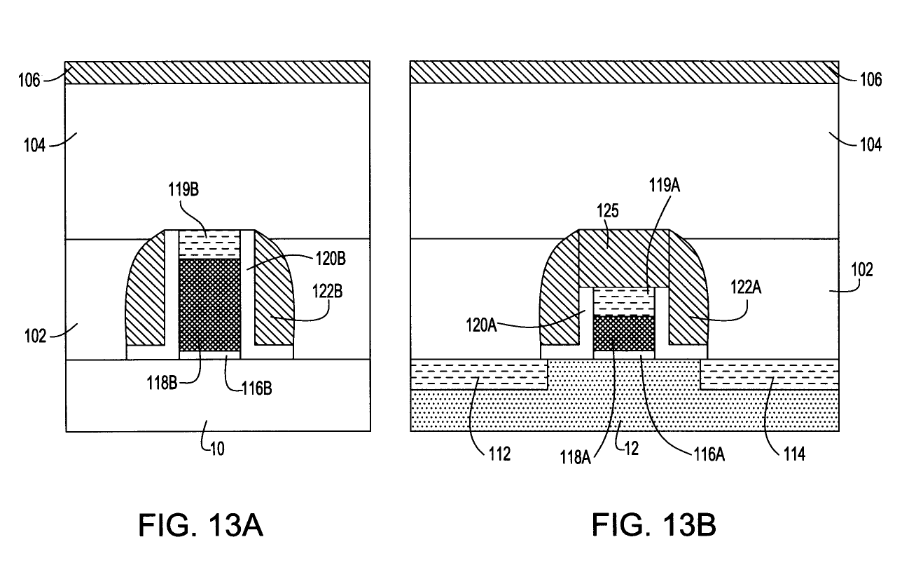

Next, another ILD layer 104 and optionally an interlevel-capping layer 106 can be deposited over the entire SRAM cell, as shown in FIGS. 13A and 13B. The ILD layer 104 may also comprise any suitable interlevel dielectric material other than silicon nitride. Consequently, the source and drain regions 112 and the gate conductor 118B with its gate silicide layer 119B are covered by the non-protective interlevel dielectric material(s) contained in the ILD layers 102 and 104, while the gate conductor 118A with its gate silicide layer 119A are covered by the silicon nitride cap 125.

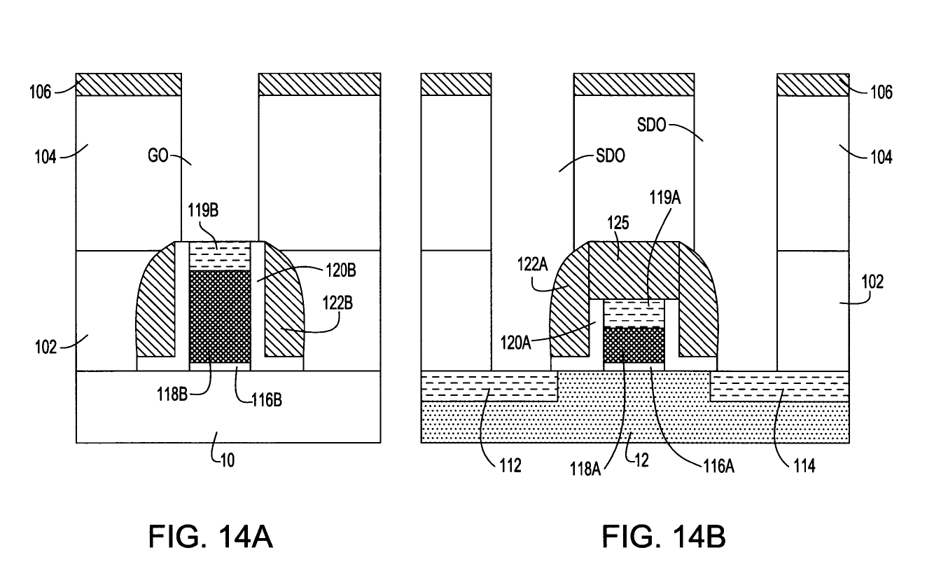

Lithography and selective etching are then carried out to form a gate contact opening GO over the gate conductor 118B and source/drain contact openings SDO over the source and drain regions 112 and 114, as shown in FIGS. 14A and 14B. Specifically, the lithography step includes applying a photoresist (not shown) to the upper surface of the interlevel-capping layer 106, exposing the photoresist to a desired pattern of radiation and developing the exposed photoresist utilizing a conventional resist developer. The pattern in the photoresist is then transferred to the interlevel-capping layer 106 and the first and second ILD layers 104 and 102 utilizing one or more dry etching steps, thereby forming the gate contact opening GO and the source/drain contact openings SDO. Suitable dry etching processes that can be used in the present invention in forming the contact openings include, but are not limited to: reactive ion etching (RIE), ion beam etching, plasma etching or laser ablation.

Preferably, a CHF₃- or a C₄F₈/CO-based RIE process, which selectively etches the non-protective interlevel dielectric materials such as silicon oxide or silicon oxynitride against silicon nitride, is carried out to selectively etch the first and second ILD layers 104 and 102 and to form the contact openings GO and SDO over the gate conductor 118B and the source and drain regions 112 and 114. Meanwhile, the silicon nitride cap 125 as well as the silicon nitride sidewall spacer 122A protect the gate conductor 118A and its gate silicide layer 119A against the CHF₃- or a C₄F₈/CO-based RIE chemistry, thereby avoiding shorting between the gate conductor 118A and the source and drain contacts SD to be formed.

Subsequently, the patterned photoresist is removed after the selective etching has been completed, and a conductive material (not shown) is filled into the contact openings GO and SDO to form the gate contact G over the gate conductor 118B and the source and drain contact SD over the source and drain regions 112 and 114, as shown in FIGS. 3A and 3B.

Other protective dielectric materials, such as silicon oxynitride, silicon carbide, silicon carbonitride, silicon carboxide, etc., can also be used for forming the dielectric cap over the gate conductor 118A.

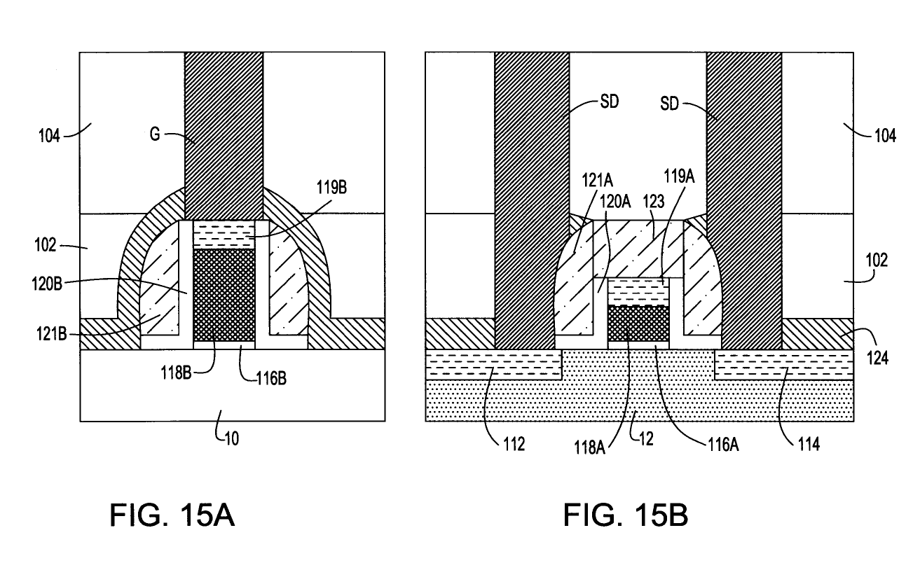

FIGS. 15A and 15B shows cross-sectional views of another improved SRAM cell similar to that of FIGS. 3A and 3B, except that this improved SRAM cell contains a blanket silicon nitride layer 124 and that the gate conductor 118A of the gate structure 22 is selectively covered by a silicon carbide cap 123.

Specifically, the source and drain regions 112 and 114 and the gate conductor 118B of the gate structure 26 are covered by a blanket silicon nitride layer 124 and two interlevel dielectric (ILD) layers 102 and 104, which may comprise any non-protective dielectric material(s) that can be selectively removed against silicon carbide contained in the dielectric cap 123. No silicon carbide is present over the source and drain regions 112 and 114 or the gate conductor 118B of the gate structure 26.

In this manner, contact openings can be readily formed over the gate conductor 118B of the gate structure 26 and the source and drain regions 112 and 114 by selectively removing a portion of the blanket silicon nitride layer 124 and the ILD layers 102 and 104, while the gate conductor 118A of the gate structure 22 is protected by the silicon carbide cap 123. Consequently, the source/drain contacts SD will not short with the gate conductor 118A of the gate structure 22, despite the presence of any lithographic alignment error. In other words, the source/drain contacts SD are “self-aligned” against the gate conductor 118A of the gate structure 22.

In a particularly preferred, but not necessary, embodiment of the present invention as shown in FIGS. 15A and 15B, the gate structures 22 and 26 comprise sidewall spacers 120A, 120B, 121A and 121B along sidewalls of the gate conductors 118A and 118B. The inner sidewall spacers 120A and 120B may comprise either protective or non-protective dielectric material(s), while the outer sidewall spacers 121A and 121B comprise the protective dielectric material (e.g., silicon carbide). Therefore, the outer sidewall spacers 121A and 121B function to protect the sidewalls of the gate conductors 118A and 118B during formation of the contact openings.

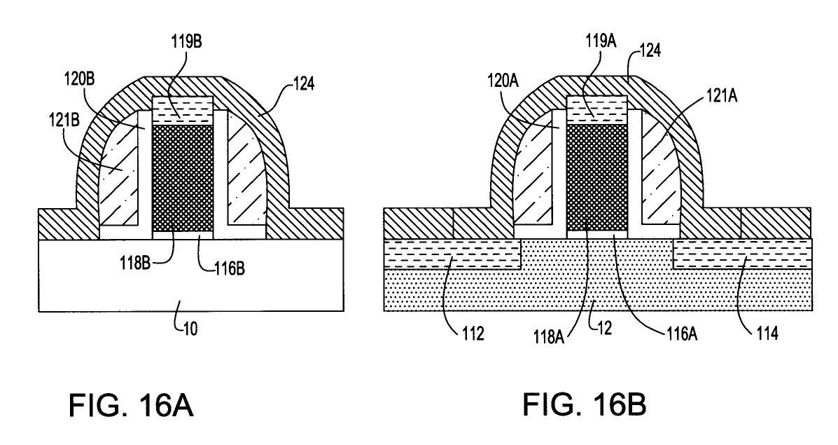

An exemplary method for forming the improved SRAM cell of FIGS. 15A and 15B is illustrated by FIGS. 16A-24B.

First, a SRAM cell having the same configuration for both gate structures 22 and 26 are formed. Specifically, the gate structures 22 and 26 each comprises a gate dielectric layer (116A or 116B), a gate conductor (118A or 118B) with an optional gate silicide layer thereover (119A or 119B), a silicon oxide sidewall spacer (120A or 120B), and a silicon carbide sidewall spacer (121A or 121B), and an optional silicon nitride layer 124 is provided to cover both gate structures 22 and 26, as shown in FIGS. 16A and 16B.

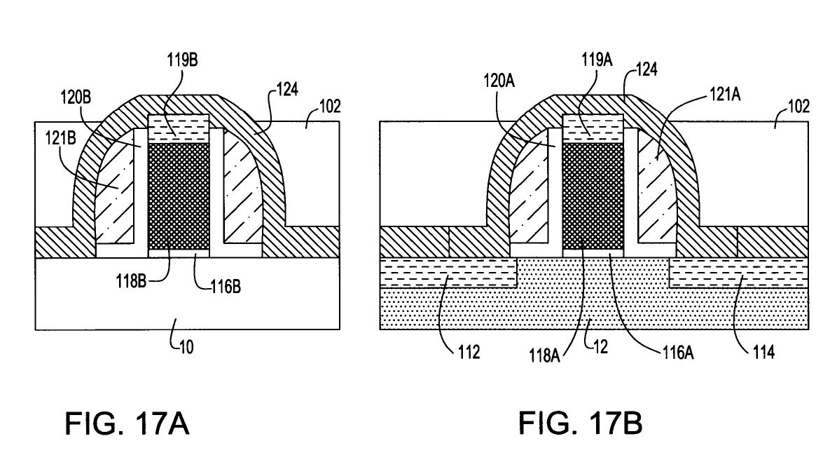

A first ILD layer 102, which may comprise any suitable interlevel dielectric material other than silicon carbide, is provided over the entire SRAM cell and then recessed by either chemical mechanical polishing (CMP) or selective etching to expose an upper surface of the silicon nitride layer 124, as shown in FIGS. 17A and 17B.

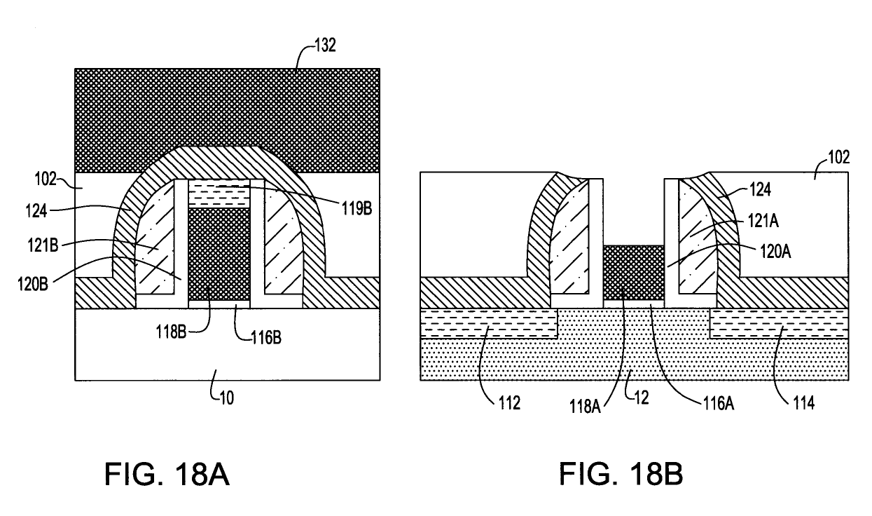

Next, a patterned resist layer 132 is formed over the SRAM cell to selectively cover portions of the SRAM cell. Specifically, the gate conductor 118B and its gate dielectric layer 119B of the gate structure 26 are selectively covered by the patterned resist layer 132, while the gate conductor 118A and its gate dielectric layer 119A of the gate structure 22 are not. Subsequently, a selective etching process is carried out using the patterned resist layer 132 as a mask to first selectively remove a portion of the blanket silicon carbide layer 124 located over the gate structure 22 and then remove an upper portion of the gate conductor 118A (including the gate silicide layer 119A), thereby forming a recess over the gate conductor 118A in the gate structure 22, as shown in FIGS. 18A and 18B. Meanwhile, the patterned resist layer 132 protects a portion of the blanket silicon carbide layer 124 located over the gate structure 26.

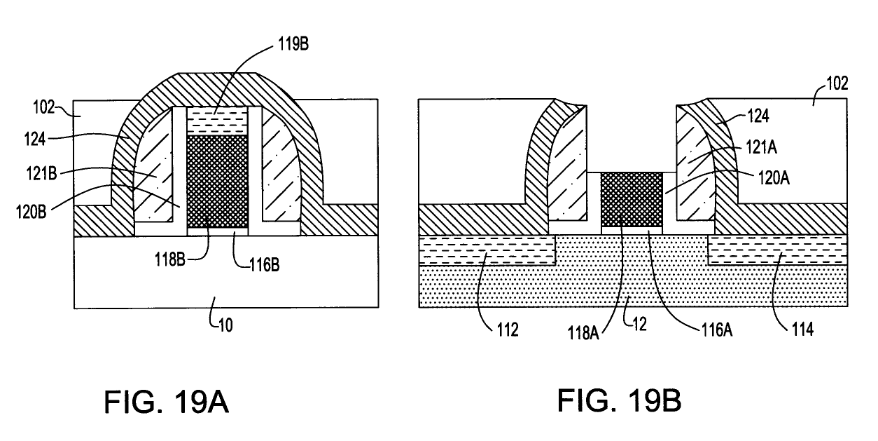

After removal of the upper portion of the gate conductor 118A (including the gate silicide layer 119A), the patterned resist layer 132 is removed from the SRAM cell by stripping, as shown in FIGS. 19A and 19B. The resist stripping step may also remove an upper portion of the silicon oxide sidewall spacer 120A in the gate structure 22.

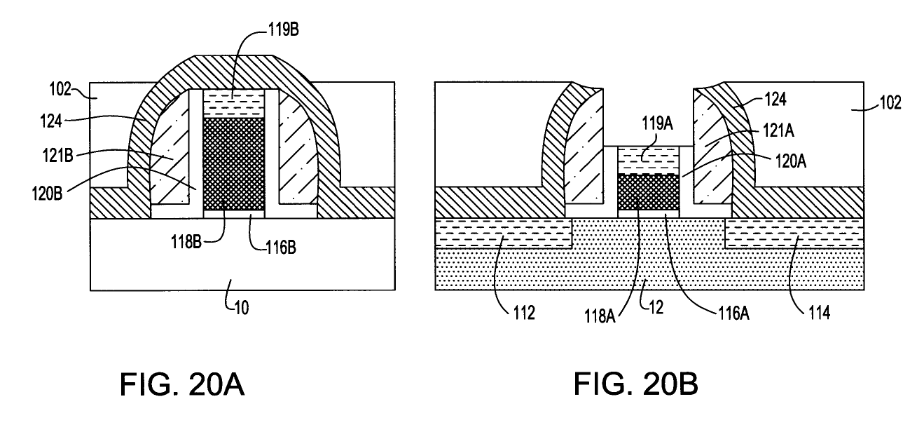

Because the gate silicide layer 119A of the gate conductor 118A is removed during the selective etching process, a silicidation process is preferably (but not necessarily) carried out to form a new gate silicide layer 119A in the recessed gate conductor 118A, as shown in FIGS. 20A and 20B.

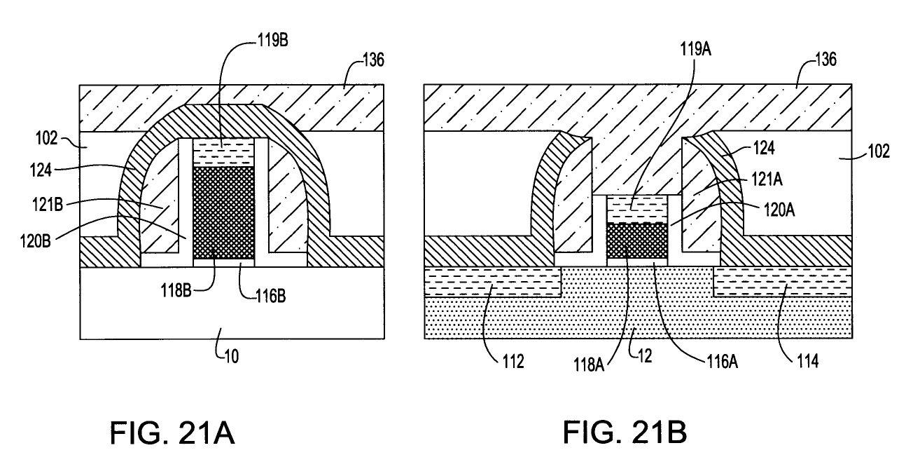

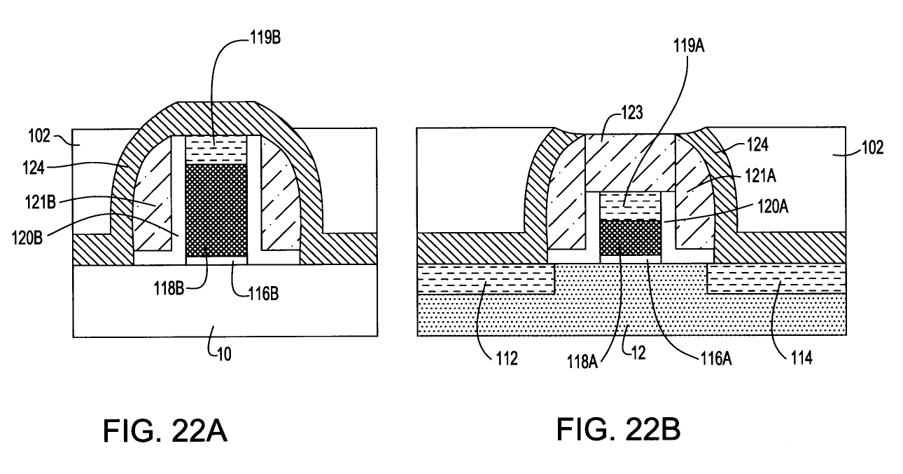

Next, a blanket silicon carbide layer 136 is deposited over the entire SRAM cell, including the gate structures 22 and 26, as shown in FIGS. 21A and 21B. A planarization step, preferably a CMP step, is then carried out to remove a portion of the blanket silicon carbide layer 136 from the gate structures 22 and 26, while another portion of the blanket silicon carbide layer 136 remains in the recess located over the gate conductor 118A and thereby forms the protective silicon carbide cap 123, as shown in FIGS. 22A and 22B.

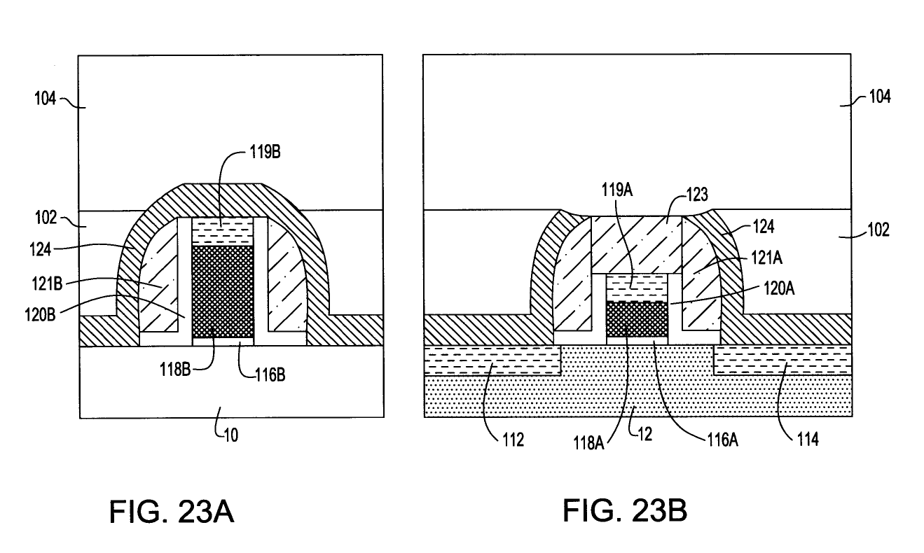

Next, another ILD layer 104 is deposited over the entire SRAM cell, as shown in FIGS. 23A and 23B. The ILD layer 104 may comprise any suitable interlevel dielectric material other than silicon carbide. Consequently, the source and drain regions 112 and the gate conductor 118B with its gate silicide layer 119B are covered by silicon nitride contained in the blanket silicon nitride layer 124 and the non-protective interlevel dielectric material(s) contained in the ILD layers 102 and 104, while the gate conductor 118A with its gate silicide layer 119A are covered by the silicon carbide cap 123.

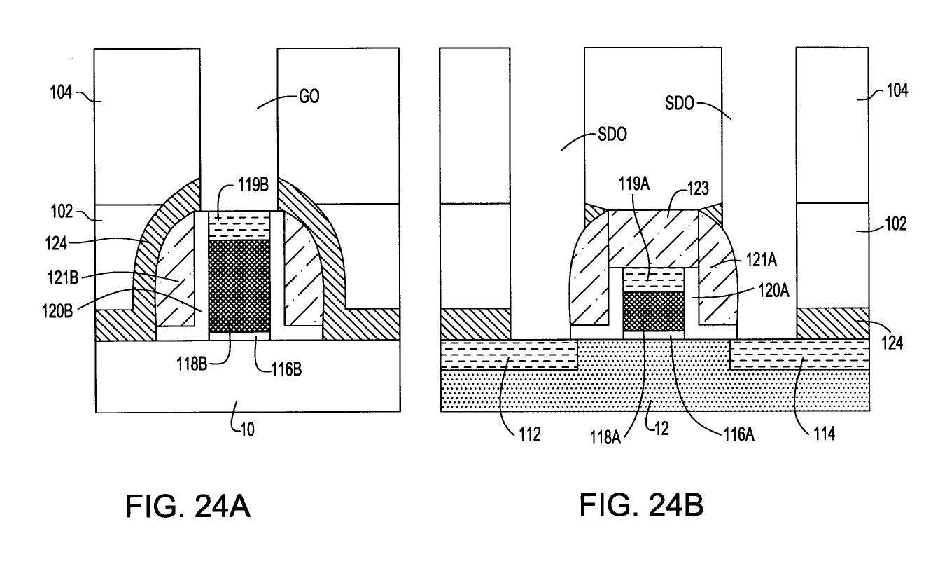

Lithography and selective etching are then carried out to form a gate contact opening GO over the gate conductor 118B and source/drain contact openings SDO over the source and drain regions 112 and 114, as shown in FIGS. 24A and 24B. Specifically, the lithography step includes applying a photoresist (not shown) to the upper surface of the ILD layer 104, exposing the photoresist to a desired pattern of radiation and developing the exposed photoresist utilizing a conventional resist developer. The pattern in the photoresist is then transferred to the ILD layers 104 and 102 and the blanket silicon nitride layer 124 utilizing one or more dry etching steps, thereby forming the gate contact opening GO and the source/drain contact openings SDO. Suitable dry etching processes that can be used in the present invention in forming the contact openings include, but are not limited to: reactive ion etching (RIE), ion beam etching, plasma etching or laser ablation.

Preferably, a CF₄— or other floro specie-based RIE process, which selectively etches silicon nitride and the non-protective interlevel dielectric materials (such as silicon oxide or silicon oxynitride) against silicon carbide, is carried out to open the blanket silicon nitride layer 124 and the first and second ILD layers 104 and 102, thereby forming the contact openings GO and SDO over the gate conductor 118B and the source and drain regions 112 and 114. The silicon carbide cap 123 as well as the silicon carbide sidewall spacer 121A protect the gate conductor 118A against the CF₄— or other floro specie-based RIE chemistry, thereby avoiding shorting between the gate conductor 118A and the source and drain contacts SD to be formed.

Note that although the description hereinabove identifies specific etching chemicals for the selective RIE steps, it is readily understood that typically a mixture of etching chemicals, such as CF₄, Ar, O₂, etc., are used to achieve the desired selectivity, and that the present invention is not limited in any manner to any specific etching chemistry.

Subsequently, the patterned photoresist is removed after the selective etching has been completed, and a conductive material (not shown) is filled into the contact openings GO and SDO to form the gate contact G over the gate conductor 118B and the source and drain contact SD over the source and drain regions 112 and 114, as shown in FIGS. 15A and 15B.

In another alternatively embodiment of the present invention, another improved SRAM cell can be provided, which is similar to that of FIGS. 15A and 15B except that this improved SRAM cell contains a blanket silicon carbide layer (not shown) over the entire structure and that the gate conductor 118A of the gate structure 22 is selectively covered by a silicon nitride cap (not shown).

As mentioned hereinabove, any suitable combination of protective and non-protective dielectric materials can be chosen for the practice of the present invention, provided that the chosen material combination enables selective removal of the protective dielectric material against the non-protective dielectric material(s), and the present invention is not limited in any manner to any specific material combination.

Although the above description is provided primarily in terms of SRAM cell structures, for simplicity and illustration purposes only, the present invention is not limited to SRAM cells, but is broadly applicable to other semiconductor device structures that contain field effect transistors (FETs) with source or drain contacts located adjacent to a gate structure, with or without modifications and variations, as readily determinable by a person ordinarily skilled in the art according to the principles described herein. Various transistors as mentioned hereinabove can be readily prepared using conventional CMOS processing techniques that are well known to those skilled in the art, and therefore details concerning their fabrication are not provided herein.

While the invention has been described herein with reference to specific embodiments, features and aspects, it will be recognized that the invention is not thus limited, but rather extends in utility to other modifications, variations, applications, and embodiments, and accordingly all such other modifications, variations, applications, and embodiments are to be regarded as being within the spirit and scope of the invention.

What is claimed is:

1. A semiconductor device comprising at least one static random access memory (SRAM) cell having at least a first gate conductor located over a channel region between a source region and a drain region, wherein the first gate conductor is covered by a dielectric cap comprising a protective dielectric material, wherein the source and drain regions are covered by non-protective dielectric material(s) that can be selectively removed against the protective material, wherein the first gate conductor has no gate contact located thereover, and wherein at least one of the source and drain regions has a source or drain contact located thereover.

2. The semiconductor device of claim 1, wherein the protective dielectric material is selected from the group consisting of silicon nitride, silicon oxynitride, silicon carbide, silicon carbonitride, and silicon carbooxide.

3. The semiconductor device of claim 1, wherein the protective dielectric material comprises silicon nitride.

4. The semiconductor device of claim 3, further comprising one or more silicon nitride spacers along sidewalls of the first gate conductor.

5. The semiconductor device of claim 1, wherein the protective dielectric material comprises silicon carbide.

6. The semiconductor device of claim 5, further comprising one or more silicon carbide spacers along sidewalls of the first gate conductor.

7. The semiconductor device of claim 1, wherein the first gate conductor comprises a gate silicide layer.

8. A semiconductor device comprising at least one static random access memory (SRAM) cell having at least a first gate conductor located over a channel region between a source region and a drain region and a second gate conductor located outside of any active region of the SRAM cell, wherein the first gate conductor is covered by a dielectric cap comprising a protective dielectric material, wherein the second gate conductor and the source and drain regions are covered by non-protective dielectric material(s) that can be selectively removed against the protective material, wherein the first gate conductor has no gate contact located thereover, wherein the second gate conductor has a gate contact located thereover, and wherein at least one of the source and drain regions has a source or drain contact located thereover.

9. The semiconductor device of claim 8, wherein the protective dielectric material is selected from the group consisting of silicon nitride, silicon oxynitride, silicon carbide, silicon carbonitride, and silicon carboxide.

10. The semiconductor device of claim 8, wherein the protective dielectric material comprises silicon nitride.

11. The semiconductor device of claim 10, further comprising one or more silicon nitride spacers along sidewalls of both the first and second gate conductors.

12. The semiconductor device of claim 8, wherein the protective dielectric material comprises silicon carbide.

13. The semiconductor device of claim 12, further comprising one or more silicon carbide spacers along sidewalls of both the first and second gate conductors.

14. A method for forming a semiconductor device, comprising:
forming at least one static random access memory (SRAM) cell having at least first and second gate conductors, wherein the first gate conductor is located over a channel region between a source region and a drain region, and wherein the second gate conductor is located outside of any active region of the SRAM cell;
selectively forming a dielectric cap over the first gate conductor, wherein the dielectric cap comprises a protective dielectric material;
depositing one or more non-protective material layers over the at least one SRAM cell, wherein the one or more non-protective material layers comprise non-protective dielectric material(s) that can be selectively removed against the protective dielectric material;
selectively removing portions of the one or more one or more non-protective material layers to form a gate contact opening that extends through the one or more non-protective material layers onto an upper surface of the second gate conductor and a source or drain contact opening that extends through the one or more non-protective material layers onto an upper surface of either the source or the drain region, wherein the dielectric cap protects the first gate conductor during selective removal of the non-protective material(s) and prevents extension of the source or drain contact opening onto the first gate conductor; and
filling the gate contact opening and the source or drain contact opening with a conductive material, thereby forming a gate contact that is located over the second gate conductor and a source or drain contact that is located directly over the source or drain region, wherein no gate contact is located over the first gate conductor.

15. The method of claim 14, wherein the protective dielectric material is selected from the group consisting of silicon nitride, silicon oxynitride, silicon carbide, silicon carbonitride, and silicon carboxide.

16. The method of claim 14, wherein the protective dielectric material comprises silicon nitride.

17. The method of claim 16, wherein sidewalls of both the first and second gate conductors are protected by one or more silicon nitride sidewall spacers.

18. The method of claim 14, wherein the protective dielectric material comprises silicon carbide.

19. The method of claim 18, wherein sidewalls of both the first and second gate conductors are protected by one or more silicon carbide sidewall spacers.

20. The method of claim 14, wherein the dielectric cap is formed by:
selectively removing an upper portion of the first gate conductor to form a recess thereover;
depositing a blanket layer of the protective dielectric material over both the first and second gate conductor; and
removing a portion of the protective dielectric material from the first and second gate conductor, wherein another portion of the protective dielectric material remains in the recess located over the first gate conductor and thereby forms the dielectric cap.
